(19) United States
(12) Patent Application Publication
(10) Pub. No.: US 2006/0022275 A1
(43) Pub. Date: Feb. 2, 2006

(54) Planar dual-gate transistor and method for fabricating a planar dual-gate transistor

(75) Inventors: Gurkan llicali, Munich (DE); Richard Johannes Luyken, Munich (DE); Wolfgang Roesner, Ottobrunn (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/177,235

(22) Filed: Jul. 7, 2005

(30) Foreign Application Priority Data
Jul. 8, 2004 (DE) 10 2004 033 147.2

(51) Int. Cl. H01L 29/78; H01L 21/336

(52) U.S. Cl. 257/366; 438/283; 438/455

(57) ABSTRACT

A method for fabricating a double-gate transistor including defining an active area on an SOI substrate, forming a first gate region on the SOI substrate, forming source/drain regions made of silicon-germanium in the active area, forming a channel region from the silicon layer of the SOI substrate, forming a layer having a planar surface above the SOI substrate, the source/drain regions, and the first gate region, bonding a second wafer to the planar surface, and forming a second gate region opposite the first gate region.

### CROSS-REFERENCE TO RELATED APPLICATION

This application claims priority to German Patent Application Serial No. 10 2004 033 147.2, which was filed on Jul. 8, 2004.

### FIELD OF THE INVENTION

The invention relates to a planar double-gate transistor and a method for fabricating a planar double-gate transistor.

### BACKGROUND OF THE INVENTION

As the scaling of the conventional planar metal oxide semiconductor field effect transistors (MOSFETs) in silicon technology advances further, the performance of the individual component is significantly impaired inter alia by the short-channel effects. Examples of undesirable short-channel effects are: a diminishing increase in the drain current as the gate voltage increases, a dependence of the threshold voltage on the operating point, and a punchthrough from the source region and drain region.

The double-gate transistor constitutes one possibility for avoiding the difficulties resulting from short-channel effects that occur and thus the limits given in the scaling. If the active area, i.e. the area of the channel region and of the source/drain region, is made sufficiently thin, short-channel effects can be drastically reduced by control effect of two gates or a surrounded gate. Consequently, the double-gate transistors represent candidates for essential components of terabit integration. However, fabrication methods by means of which double-gate transistors can be fabricated and which can be realized in a simple manner have not yet been established.

Various concepts are being discussed and tested for the fabrication of double-gate transistors. Examples of such concepts are vertical transistors, fin transistors or planar structures with a replacement gate. However, all these concepts use complicated processes that have not been tried and tested hitherto in terms of production engineering in silicon technology. The overall fabrication process is also very complex and costly. Furthermore, no planar surface of the individual regions (e.g. of the gate) is produced for a vertical transistor, thereby causing an impairment of the current flow through the individual regions.

One problem in the fabrication of a planar double-gate transistor, moreover, is that highly complex method steps are required during the fabrication. If the dimensions of the double-gate transistor are reduced further, this increases the demands placed on precise control of each individual one of the many highly complex fabrication steps, one of which constitutes doping, for example, by means of which the source region and the drain region are produced. In particular a subsequent diffusion of the dopant from the source/drain regions into the channel region poses a major problem.

A further difficulty in the fabrication of a planar double-gate transistor is ensuring an exact alignment of the two respective gates, to put it another way ensuring that the two gates of the transistor are arranged in a fixed spatial relationship with respect to one another. In the case of a planar double-gate transistor, the two gates of the transistor are arranged one above the other at the same location of the substrate on both sides of a channel region of the transistor that is arranged between the source terminal and drain terminal. In other words the channel region is arranged between the two gates. Given customarily projected gate lengths in the range of approximately 10 nm to 20 nm, the high requirements made of the accuracy of the alignment become apparent.

DE 102 23 709 A1 discloses a method for fabricating a double-gate transistor, a first gate region being formed on a silicon-on-insulator substrate of a first wafer and a plane surface being formed thereon. Furthermore, a second wafer is bonded to the plane surface of the first wafer and a second gate region is formed opposite the first gate region in the silicon-on-insulator substrate.

U.S. 2002/0105039 A1 discloses a method for fabricating a double-gate transistor having a front poly gate electrode and a rear implantation region, the two gates being separated by two gate dielectrics having a thin silicon layer, serving as channel region, in between.

### SUMMARY OF THE INVENTION

A method for fabricating a planar double-gate transistor, comprising the steps of defining an active area on a silicon-on-insulator substrate of a first wafer, forming a first gate region on the silicon-on-insulator substrate of the first wafer, forming source/drain regions from a layer made of silicon-germanium in the active area, the silicon layer that remains between the source and drain regions being provided as a channel region, forming a layer having a plane surface above the silicon-on-insulator substrate, the source/drain regions and the first gate region, bonding a second wafer to the plane surface of the first wafer, and forming a second gate region opposite the first gate region.

### BRIEF DESCRIPTION OF THE DRAWINGS

Exemplary embodiments of the invention are illustrated in the figures and are explained in more detail below.

In the figures:

FIG. 1 shows a schematic plan view of a planar double-gate transistor, showing a schematic layout of a double-gate transistor according to the invention;

FIG. 2 shows a schematic cross-sectional representation of a layer arrangement according to the invention after substeps of a method in accordance with a first exemplary embodiment of the invention which principally serve for forming a first gate region of the double-gate transistor;

FIG. 3 shows a schematic cross-sectional representation of a layer arrangement according to the invention after additional substeps of the method in accordance with the first exemplary embodiment of the invention which principally serve for forming a channel region and source/drain regions;

FIG. 4 shows a schematic cross-sectional representation of a layer arrangement according to the invention after additional substeps of the method in accordance with the first exemplary embodiment of the invention which principally serve for preparing for a wafer bonding;

FIG. 5 shows a schematic cross-sectional representation of a layer arrangement according to the invention after additional substeps of the method in accordance with the first exemplary embodiment of the invention which principally serve for forming a second gate region;

FIG. 6 shows a schematic cross-sectional representation of a layer arrangement according to the invention after substeps of the method in accordance with the first exemplary embodiment of the invention which principally serve for forming an insulation of the double-gate transistor;

FIG. 7A shows a schematic cross-sectional representation of a layer arrangement according to the invention after substeps of a method in accordance with the first exemplary embodiment of the invention which principally serve for forming contacts for the gate regions of the double-gate transistor;

FIG. 7B shows a schematic cross-sectional representation of a layer arrangement according to the invention after substeps of a method in accordance with a second exemplary embodiment of the invention which principally serve for forming contacts for the gate regions of the double-gate transistor;

FIG. 8 shows a schematic cross-sectional representation of a layer arrangement according to the invention after substeps of the method in accordance with an alternative method of the invention which principally serve for forming a silicide layer; and

FIG. 9 shows a schematic cross-sectional representation of a layer arrangement according to the invention after substeps of the alternative method of the invention which principally serve for forming contacts for the gate regions of the double-gate transistor.

### DETAILED DESCRIPTION OF PREFERRED EMBODIMENTS OF THE INVENTION

The invention is based on the problem of providing a planar double-gate transistor and a simple method for fabricating a planar double-gate transistor in the case of which it is possible to have recourse to known and simple method steps of silicon technology and in the case of which an accurate alignment of the two gates with respect to one another is achieved.

The problem is solved by means of the planar double-gate transistor and the method for fabricating a double-gate transistor having the features in accordance with the independent patent claims.

In a method according to the invention, an active area is defined on a silicon-on-insulator substrate of a first wafer, then a first gate region is formed on the silicon-on-insulator substrate of the first wafer and source/drain regions are formed in the active area by means of a layer of a material made of silicon and germanium, the silicon layer that remains between the source/drain regions clearly being provided as a channel region. A next step is forming a channel region from the silicon layer of the silicon-on-insulator substrate of the first wafer, followed by forming a layer having a plane surface above the silicon-on-insulator substrate, the source/drain regions and the first gate region. A second wafer is bonded to the plane surface of the first wafer and a second gate region opposite the first gate region is then formed.

A planar double-gate transistor has a source region and a drain region, a channel region arranged between the source region and the drain region, and precisely two gate regions arranged on mutually opposite sides of the channel region. Furthermore, the source region and the drain region have, as material, a mixture of silicon and germanium, the germanium proportion preferably lying between approximately 20 atomic percent and 40 atomic percent. Preferably, the source region and the drain region furthermore have carbon as a material.

With the method according to the invention, a planar double-gate transistor is fabricated in a simple and cost-effective manner by means of known method steps of silicon technology, it being possible to effectively prevent the diffusion of doping atoms into the channel region.

Preferred developments of the invention emerge from the dependent claims. Preferred developments which relate to the method for forming a double-gate transistor also apply to the planar double-gate transistor according to the invention.

Preferably, the silicon-germanium layer furthermore has carbon as material. This can clearly be understood to mean that the layer from which the source/drain regions are formed is made of silicon-germanium-carbon, that is to say is a silicon-germanium-carbon layer.

With the method according to the invention, a planar double-gate transistor is fabricated in a simple and cost-effective manner by means of known method steps of silicon technology, it being possible to effectively prevent the diffusion of doping atoms into the channel region. In particular, the use of a silicon-germanium-carbon layer (SiGe:C layer) for forming the source/drain regions allows the fabrication method to be simplified and to be made more flexible since, on the one hand, silicon-germanium effectively drastically reduces the diffusion of dopants into the channel region of the double-gate transistor, particularly if carbon is additionally incorporated, and, on the other hand, etchants are known which are selective with respect to silicon-germanium-carbon, thus resulting in additional degrees of freedom for etching steps and etchants in the fabrication method.

In this application, silicon-germanium-carbon (SiGe:C) is understood to mean a material made of silicon-germanium with small amounts of carbon, that is to say silicon with which a certain proportion, for example between 20 atomic percent and 40 atomic percent, of germanium is admixed and furthermore a small proportion of carbon is admixed, preferably between 2 atomic percent and 5 atomic percent. Silicon-germanium-carbon may be present as a crystalline structure in the case of which, in a silicon crystal, some of the silicon atoms have been replaced by germanium atoms, and into which small amounts of carbon have also been incorporated.

Preferably, the insulator of the silicon-on-insulator substrate is fabricated from silicon oxide, silicon oxide being understood to mean SiO₂.

In one development, in the case of defining the active area, a MESA structure corresponding to the active area is formed from the silicon layer of the silicon-on-insulator substrate of the first wafer.

This clearly means that partial regions of the silicon layer of the silicon-on-insulator substrate, i.e. of the upper layer of the SOI substrate, are removed by means of etching, while those partial regions of the silicon layer of the SOI substrate which correspond to the defined active area remain on the insulator layer. These remaining partial regions form a structure which is similar to a pedestal or table and is therefore clearly designated as a MESA structure. Consequently, forming the MESA structure involves removing the silicon layer of the SOI substrate and uncovering the underlying insulator layer, which is preferably formed from silicon oxide (SiO₂), on which further layers may subsequently be applied.

Preferably, a first insulator layer is formed on the silicon-on-insulator substrate of the first wafer in the regions not covered by the MESA structure, which first insulator layer has the same thickness as the silicon layer of the MESA structure.

This clearly means that an insulator layer, preferably made of silicon nitride (Si₃N₄) is formed in the regions which are not covered by the MESA structure of the silicon, that is to say that the MESA structure is a really completely surrounded by an insulator layer having the same thickness as the silicon layer. This insulator layer may serve as an etch stop layer for later etching processes and is an efficient possibility for forming an insulation between the two gate regions of the planar double-gate transistor, that is to say for electrically decoupling the two gate regions from one another. In particular, the channel region is also insulated from the gate regions and the source/drain regions by means of the insulator layer.

In one development, the formation of the first gate region on the silicon-on-insulator substrate has the following steps of: forming a first gate insulating layer on the silicon-on-insulator substrate, and forming and patterning a first layer made of an electrically conductive material on the first gate insulating layer. Furthermore, partially encapsulating the first gate region with an electrically nonconductive material.

The electrically conductive material from which the layer on the first gate insulating layer is formed is preferably polysilicon, from which the first gate region is subsequently formed. The encapsulation of the first gate region, that is to say the first layer made of conductive material, may be formed from silicon oxide and/or silicon nitride. The polysilicon may be doped in an additional substep.

The first gate insulating layer may be formed from silicon oxide preferably produced by partial oxidation of the silicon layer of the silicon-on-insulator substrate of the first wafer.

Forming a silicon oxide layer by means of a partial, preferably thermal, oxidation of the silicon layer of the SOI substrate provides an effective possibility for forming a gate insulating layer.

In one development, the formation of source/drain regions has the following steps of: patterning the uncovered silicon layer of the silicon-on-insulator substrate of the first wafer, the encapsulation of the first gate region being used as a mask, and patterning the first insulator layer. Furthermore, the insulator layer of the silicon-on-insulator substrate of the first wafer is patterned and the silicon-germanium-carbon layer of the source/drain regions is formed.

The silicon-germanium-carbon layer is preferably formed from Si₁₋ₓGeₓC_{y}, where the value of x preferably lies in the range of 0.2 to 0.4 and the value of y preferably lies in the range of 0.02 to 0.05.

Using the encapsulation of the first gate region as a mask for patterning the uncovered silicon layer makes it possible to ensure in a simple manner that the second gate region that is subsequently formed is situated precisely beneath the first gate region, that is to say that the process is self-aligning.

During subsequent etching steps, the silicon-germanium-carbon of the source/drain regions may be used as an etch stop layer. Examples of suitable etchants which are selective with respect to silicon-germanium-carbon are ethylene diamine pyrocatechol (EDP), tetramethylammonium hydroxide (TMAH), potassium hydroxide (KOH) or choline (2-hydroxyethyl-trimethyl-ammonium hydroxide). A high selectivity results given a proportion of more than 20% of Ge.

The formation of the silicon-germanium-carbon layer may be carried out by means of selective epitaxy.

The formation of the silicon-germanium layer may be carried out by means of selective epitaxy.

Selective epitaxy constitutes a method by means of which a good control of the formation of the silicon-germanium-carbon layer or of the silicon-germanium layer is achieved, that is to say that, by way of example, the thickness of a deposited layer can be defined very exactly. Furthermore, it is also possible to take account of the lattice orientations of the individual layers, that is to say of the layer on which a second layer is formed and of the layer which is formed.

The formation of a layer having a plane surface may be carried out by means of forming a plane first layer made of electrically nonconductive material on the silicon-germanium-carbon layer on the source/drain regions and the first gate region.

As a result of the planarization of the surface, the latter can be bonded to a second surface more easily in a subsequent wafer bonding step. The planarization is preferably carried out by means of chemical mechanical polishing. Moreover, after the planarization, a chemical and/or plasma activation step may be carried out, whereby the subsequent wafer bonding step can be carried out more simply and more effectively. The first layer made of electrically nonconductive material is preferably formed from silicon oxide.

In one development, the formation of the second gate region has the following steps of: patterning the insulator of the silicon-on-insulator substrate and uncovering the silicon layer of the silicon-on-insulator substrate, and forming a gate insulating layer from a first thin nonconductive layer on the silicon layer of the silicon-on-insulator substrate. Furthermore, a second thin nonconductive layer is formed on the layer made of silicon-germanium-carbon of the source/drain regions and a second sidewall layer made of a nonconductive material is formed.

The material of the second sidewall layer is preferably silicon nitride and/or silicon oxide.

The thin nonconductive layer is preferably produced by means of oxidation of the silicon layer of the silicon-on-insulator substrate and of the layer made of silicon-germanium-carbon of the source/drain regions.

The oxidation of the silicon layer provides a simple method for forming a silicon oxide layer as insulation. The thin nonconductive layer formed by oxidation on the silicon-germanium-carbon of the source/drain regions can be used as a layer which prevents or at least reduces a diffusion of the dopants during the implantation of dopants.

Preferably, the formation of the second gate region furthermore has the following steps of: forming a second layer made of an electrically conductive material on the gate insulating layer, etching back the silicon-germanium-carbon layer of the source/drain regions, and forming a passivation layer on the entire wafer of the silicon-on-insulator substrate, and subsequent planarization.

The second gate insulating layer, from which the second gate region of the double-gate transistor is formed, is preferably made of polysilicon, which is preferably doped. Etching back the silicon-germanium-carbon layer makes it possible to ensure in a simple manner that a short circuit, that is to say an electrically conductive connection, cannot occur between the source/drain regions and the two gate regions. The passivation layer is preferably formed from silicon oxide and serves for insulating the planar double-gate transistor, that is to say that it insulates the planar double-gate transistor toward the outside.

In one development, the method furthermore has the steps of contact-connecting the first gate region and contact-connecting the second gate region.

Contact-connecting the first gate region may have the following substeps of: removing a part of the passivation layer, thereby uncovering a partial region of the second gate region. Removing the conductive layer of the second gate region in the partial region that has been uncovered, thereby uncovering a partial region of the first insulator layer. Removing the first insulator layer in the partial region that has been uncovered, thereby uncovering a partial region of the first gate region, and forming the contact-connection of the first gate region.

By means of these substeps, a hole or trench is clearly formed which enables the two gate regions to be contact-connected toward the outside. The contact-connection may then be effected by means of a metal layer formed in the hole. Preferably, prior to the formation of the metal layer serving for the contact-connection, a layer made of silicide is formed in the uncovered regions of the gate regions in order to reduce the contact resistance of the contact-connection.

Preferably, prior to the removal of the first insulator layer, a nonconductive layer is formed by oxidizing the uncovered regions of the second conductive layer which forms the second gate region.

By means of the oxidation of the uncovered regions of the second conductive layer which forms the second gate region, an insulation between the contact-connection of the first gate region and the second gate region is formed in a simple manner. The second gate region is then contact-connected separately, thereby affording the possibility that a different voltage can be applied to the first gate region and to the second gate region. The two gate regions can thus be controlled independently of one another. Consequently, a double-gate transistor formed in this way can be used as a memory cell which can store two bits of information.

The described method for fabricating a double-gate transistor provides a planar double-gate transistor by means of simple, known, tried and tested and cost-effective process steps. By using the encapsulation of the first gate region as a mask when patterning the silicon layer of the SOI substrate and the insulator layer of the SOI substrate, the method is a self-aligning method and the first gate region and the second gate region lie exactly opposite one another.

In particular through the use—unknown in the prior art—of silicon-germanium-carbon in connection with the SOI technique, it is possible to provide a method which provides a planar double-gate transistor in a particularly simple and effective manner.

To summarize, the invention relates to a planar double-gate transistor and a method for fabricating a planar double-gate transistor in the case of which recourse is had to known, simple and cost-effective substeps of semiconductor technology. By virtue of the individual substeps being combined in a manner according to the invention, a planar double-gate transistor is fabricated in which short-channel effects are drastically reduced by the control effect of two gate regions. In particular, the fabrication process is simplified by means of the use—unknown hitherto in the fabrication of double-gate transistors—of a layer made of silicon-germanium-carbon as source/drain region. However, the use of a silicon-germanium layer, i.e. a layer not having any carbon, also already affords the advantage that the silicon-germanium layer drastically reduces diffusion of dopants.

In particular the use of silicon-germanium-carbon has advantages over the conventional materials. One advantage is that silicon-germanium-carbon is a suitable material for drastically reducing diffusion of dopants, e.g. a diffusion of dopants into the channel region of the planar double-gate transistor, thereby enabling better and more reliable control of the channel region. A second advantage is that additional degrees of freedom are provided in the fabrication process because it is possible to use etchants which act selectively with respect to silicon-germanium-carbon.

An additional advantage of the method according to the invention is that the source/drain regions are formed on a thick silicon layer of a silicon-on-insulator layer substrate wafer, that is to say the layer situated beneath the insulator layer (carrier layer), while in the known methods the source/drain regions are formed on a thin silicon layer of the silicon-on-insulator substrate, that is to say the silicon layer situated above the insulator layer. This simplifies the formation of the layer from which the source/drain regions are produced since, by way of example, mechanical stress is reduced during the formation.

The substeps of a method according to the invention for fabricating a planar double-gate transistor in accordance with an exemplary embodiment of the invention are explained in more detail referring to the figures.

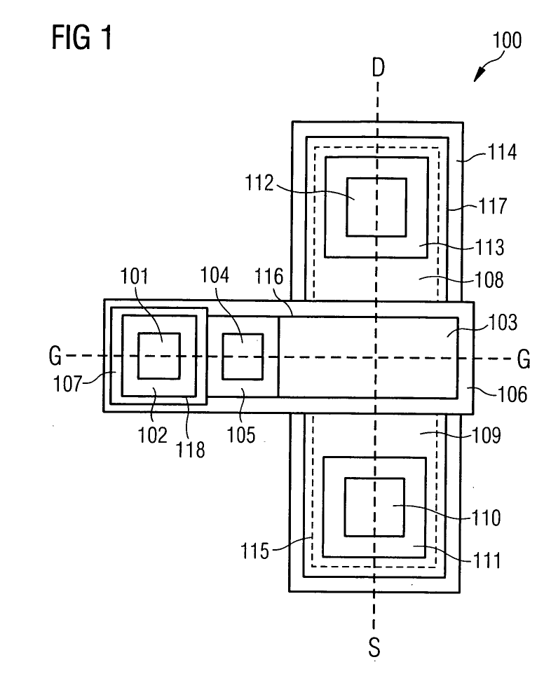

FIG. 1 shows a schematic plan view showing a schematic layout of a double-gate transistor 100 according to the invention. FIG. 1 principally serves for illustrating the schematic layout of the double-gate transistor 100 and illustrating the various photolithographic regions which are defined by means of photolithographic masks during a method for fabricating the double-gate transistor 100 according to the invention that is described below. In order to enhance clarity, an encapsulation of the entire double-gate transistor 100 is not illustrated in FIG. 1.

A double-gate transistor 100 according to the invention has a lower gate region, which is concealed in FIG. 1 and is only indicated by a first contact-connection 101, preferably made of a metal, and a first contact region 102, preferably made of a silicide. Furthermore, the double-gate transistor 100 has an upper gate region 103, which is preferably formed from polysilicon. Furthermore, a second contact-connection 104 and a second contact region 105 are illustrated for the upper gate region 103. The second contact-connection 104 is preferably formed from a metal, while the second contact-connection region 105 is preferably formed from silicide.

The double-gate transistor 100 shown in FIG. 1 furthermore has an encapsulation 106, which electrically insulates the region of the upper gate region 103 and of the lower gate region 101 toward the outside. The encapsulation 106 is preferably formed from silicon nitride (Si₃N₄). FIG. 1 furthermore illustrates a first layer made of silicon oxide 107. The first layer made of silicon oxide 107 serves for encapsulating the contact-connection 101 of the lower gate region and thus for insulating the lower gate region from the upper gate region 103.

Furthermore, the double-gate transistor 100 according to the invention has a drain region 108 and a source region 109, which are both formed from Si₁₋ₓGeₓC_{y}, where the value of x preferably lies in the range of 0.2 to 0.4 and the value of y preferably lies in the range of 0.02 to 0.05. A third contact-connection 110, which is preferably formed from metal, and a third contact region 111 are illustrated in the source region 109. The third contact region 111 is preferably formed from silicide. A fourth contact-connection 112, which is preferably formed from metal, and a fourth contact region 113 are illustrated in the drain region 108. The fourth contact region 113 is preferably formed from silicide.

FIG. 1 illustrates an encapsulation 114 of the active region, i.e. of the source/drain region and of a channel region (not visible in FIG. 1), which serves for electrically insulating the source/drain region toward the outside. The encapsulation is preferably formed by means of silicon oxide.

In order to facilitate understanding of the subsequent figures and of the method for fabricating a planar double-gate transistor that is explained with reference to the subsequent figures, FIG. 1 additionally depicts lines along which the subsequently illustrated cross-sectional views are taken and regions in which photolithographic steps are carried out during the method for fabricating a planar double-gate transistor.

Specifically, these are the sectional line G-G leading along the gate regions of the planar double-gate transistor, and the sectional line S-D leading along the source/drain regions of the planar double-gate transistor. Furthermore, the line 115 is used to indicate a photolithographic mask used in a first photolithographic step, in which the active region, that is to say the source/drain region and the channel region of the planar double-gate transistor is defined. The line 116 is used to indicate a photolithographic mask used in a second photolithographic step, in which the region of the gate regions of the planar double-gate transistor is defined. The line 117 is used to indicate a photolithographic mask used in a third photolithographic step, in which the active region, that is to say the source/drain region and the channel region of the planar double-gate transistor, is once again defined, that is to say is redefined. The line 118 is used to indicate a photolithographic mask used in a fourth photolithographic step, in which a contact hole to the lower gate region of the planar double-gate transistor is defined.

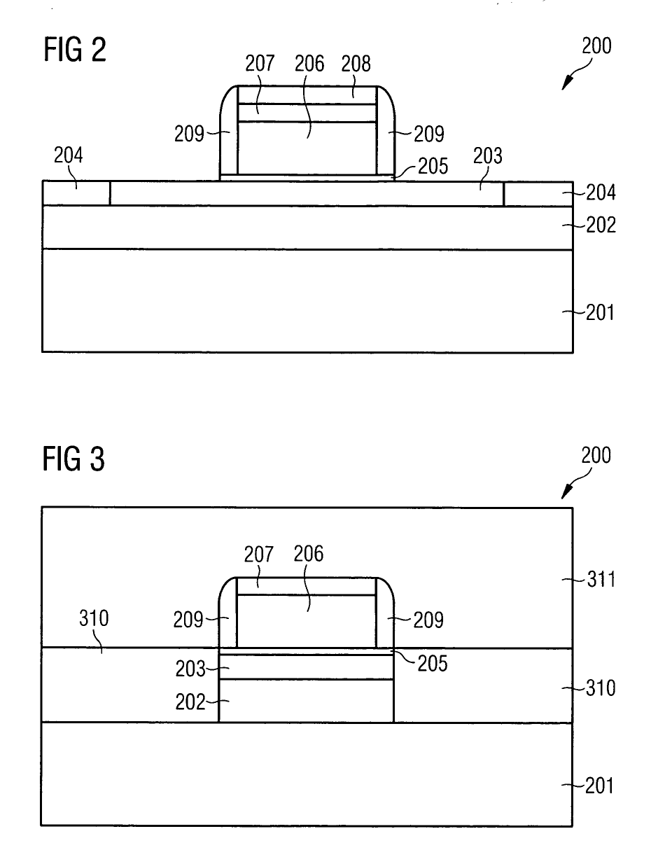

FIG. 2 shows a cross-sectional view of a layer arrangement 200 after first substeps of a method according to the invention for fabricating a planar double-gate transistor 100, the cross-sectional view, as well as the cross-sectional views of FIGS. 3 to 6, being shown along the line S-D from FIG. 1. The individual substeps are described in more detail below.

The starting point for the method according to the invention for fabricating a planar double-gate transistor is a conventional silicon-on-insulator substrate wafer (SOI wafer) having a first layer made of silicon 201 (carrier), a first layer made of silicon oxide 202 (insulator) and a second silicon layer 203. Afterward, by means of a first photolithography step, the active region of the double-gate transistor is defined, that is to say an etching step is effected to define the region in which the source region and the drain region are formed by means of subsequent substeps. In this case, a photoresist is applied to the second silicon layer 203 using a first mask, which corresponds to the mask indicated by means of the line 115 in FIG. 1. The second silicon layer 203 is subsequently etched in a first etching step, thereby forming a MESA structure of the second silicon layer 203, that is to say that a pedestal- or tablelike structure of the second silicon layer 203 is formed, the form of which corresponds to the source/drain regions to be formed later and the channel region. Residues of the photoresist are subsequently removed. The buried first silicon oxide layer 202 may be used as an etch stop layer for the first etching step.

A first silicon nitride layer 204 is subsequently formed in the region in which the silicon layer 203 has been removed by means of the first etching step. The first silicon nitride layer 204 is preferably formed by means of epitaxy and has the same thickness as the second silicon layer 203. The silicon nitride layer 204 serves as first insulation. The first silicon nitride layer 204 subsequently serves as encapsulation for electrical insulation between the source/drain regions to be formed and the lower gate region to be formed of the planar double-gate transistor and also for insulating the two gate regions from one another. In particular, the first silicon nitride layer 204 also serves for insulating and defining the channel region, which is formed from the second silicon layer 203 in subsequent substeps. The first silicon nitride layer 204 and the second silicon layer 203 have the same thickness, thereby preventing the formation of undesired spacers and simplifying subsequent planarization steps. If the second silicon layer 203 and thus the silicon nitride layer 204 to be formed have such a large thickness that mechanical stress would occur, a layer made of silicon oxide may be applied to the first silicon nitride layer 204, thereby reducing mechanical stress. The first silicon nitride layer 204 is used as an etch stop layer in a later method step.

The surface of the layer arrangement is subsequently planarized, the second silicon layer 203 being used as a stop. The planarization is preferably carried out by means of chemical mechanical polishing (CMP). The planarization ensures that a level surface is produced and that the thicknesses of the second silicon layer 203 and of the first silicon nitride layer 204 are identical.

In a next method step, the second silicon layer 203 is partially oxidized, so that a second silicon oxide layer 205 is formed, which may subsequently serve as a gate insulating layer for the lower gate region. A first layer 206 made of polysilicon, a second layer 207 made of silicon nitride and a third layer 208 made of silicon oxide are subsequently formed. The lower gate region is formed later from the first polysilicon layer 206 and the encapsulation of the lower gate region is formed later from the second silicon nitride layer 207. The third silicon oxide layer 208 may subsequently be used as a protective layer for the second silicon nitride layer 207 in an etching step.

A second photolithographic step is subsequently carried out. For this purpose, a photoresist is applied using a second mask, which corresponds to the region indicated by means of the line 116 in FIG. 1. Afterward, the third silicon oxide layer 208, the second silicon nitride layer 207 and the first layer made of polysilicon 206 are etched in a second etching step. The second silicon oxide layer 205, which forms the gate insulating layer of the lower gate region, is used as an etch stop in this case. The residual photoresist is subsequently removed.

Afterward, a third layer made of silicon nitride 209 is formed, the formation preferably being carried out by means of conformal deposition. The third silicon nitride layer is subsequently etched anisotropically in a third etching step, thereby forming spacers 209 made of silicon nitride. The second silicon oxide layer 205 is used as an etch stop layer in the third etching step. The spacers 209 made of silicon nitride serve for encapsulating the lower gate. The second silicon oxide layer 205 is subsequently etched in a fourth etching step; the encapsulation of the lower gate region, that is to say the spacers 209, may serve as a mask in this case. The first polysilicon layer 206 is preferably doped.

The substeps described with reference to FIG. 2 have formed the lower gate region of the planar double-gate transistor and the encapsulation thereof on the SOI wafer.

An explanation is given below, with reference to FIG. 3, of substeps of the method for fabricating a planar double-gate transistor which principally serve for forming a channel region and source/drain regions.

Proceeding from the layer sequence illustrated in FIG. 2, the second silicon layer 203 is selectively etched anisotropically in a fifth etching step, the lower gate region, that is to say the spacers 209, serving as a mask. The first silicon oxide layer 202 of the SOI wafer is used as an etch stop layer. The first silicon nitride layer 204 is subsequently etched by means of a selective anisotropic sixth etching step. The first silicon oxide layer 202 of the SOI wafer is used as an etch stop layer. By means of the sixth etching step, the entire first silicon nitride layer 204 is removed apart from in the region situated beneath the lower gate region. The region cannot be seen in FIG. 3 since it is situated, in the view of FIG. 3, behind the sectional line S-D. The remaining regions of the first silicon nitride layer 204 serve, as already mentioned above, for insulating the source/drain regions that are to be formed later from the gate regions of the planar double-gate transistor and for insulating the channel region.

When carrying out the sixth etching step, it must be taken into consideration that, during the sixth etching step, the spacers 209 are also exposed to the etchant, and it can happen as a result of this that the spacers 209 are etched by the etchant, that is to say that a portion of the spacers 209 made of silicon nitride is removed. In order to ensure a sufficient encapsulation, i.e. insulation, of the lower gate region, it is ensured during the formation of the spacers 209 that they still have a sufficient insulating property even after the sixth etching step, that is to say that they are formed with a sufficient thickness. As an alternative, it is also possible to form a thin layer made of silicon oxide on the spacers 209, which protects the spacers 209 during the sixth etching step.

After the sixth etching step, the first silicon oxide layer 202 of the SOI wafer is a etched in a seventh etching step. This is preferably carried out by means of an anisotropic etching. For the seventh etching step, the first silicon layer 201 of the SOI wafer may be used as an etch stop and the spacers 209 may again be used as a mask.

Afterward, a silicon-germanium-carbon layer 310 (SiGe:C) is formed selectively in the active region, that is to say the region in which the source region and the drain region are formed. The formation of the silicon-germanium-carbon layer is carried out by means of epitaxy. The atomic ratio of the silicon (Si):Germanium(Ge) lies in the range of 4:1 to 3:2 and the proportion of carbon (C) lies in the range of 2 to 5 atomic percent. The formation by selective epitaxy prevents mechanical stress from forming between the first silicon layer 201 and the silicon-germanium-carbon layer 310 since the lattice constants of the materials of the two layers match one another, that is to say do not deviate greatly from one another, if the proportions of silicon, germanium and carbon are chosen in a suitable manner.

Afterward, a fourth layer made of silicon oxide 311 is formed on the layer sequence and subsequently planarized. The planarization is preferably effected by means of chemical mechanical polishing.

A channel region and the source/drain regions of the planar double-gate transistor are formed by means of the substeps described with reference to FIG. 3. In this case, the channel region is formed from the second silicon layer 203 of the SOI wafer.

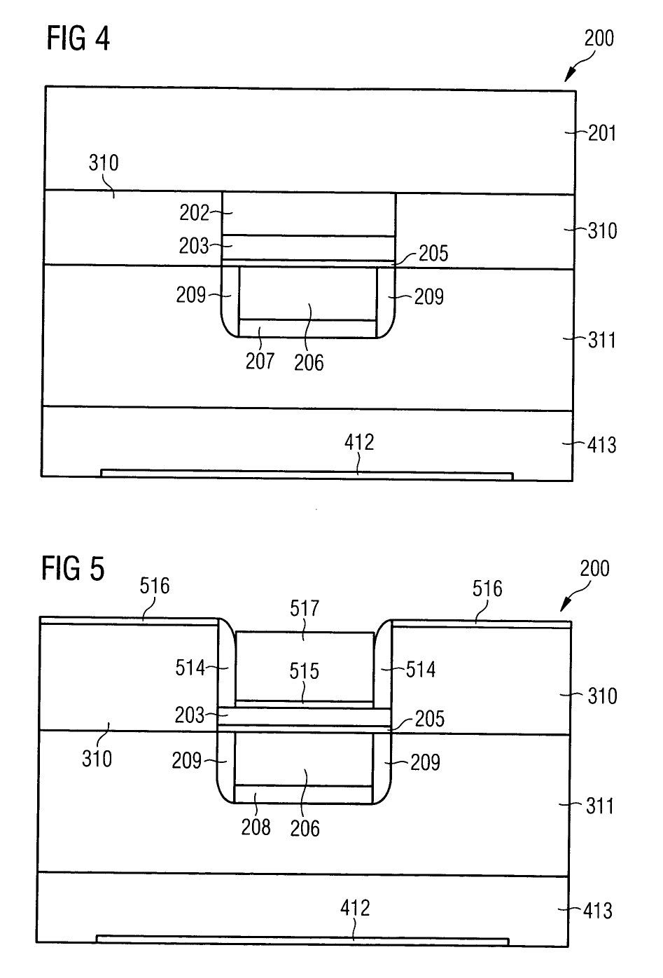

An explanation is given below, with reference to FIG. 4, of substeps of the method for fabricating a planar double-gate transistor which principally serve for preparing for and carrying out a wafer bonding step.

The fourth silicon oxide layer 311 of the layer sequence from FIG. 3, after it has been planarized, is activated chemically or by means of plasma. An auxiliary wafer 412 has a thick fifth layer made of silicon oxide 413. If the material of the auxiliary wafer 412 is silicon, the fifth silicon oxide layer 413 may be formed by means of a thermal oxidation of the auxiliary wafer 412. The layer sequence illustrated in FIG. 3 is bonded onto the fifth silicon oxide layer 413 of the auxiliary wafer 412 by the planarized surface of the fourth silicon oxide layer 311. The layer sequence is reversed for the subsequent substeps. Therefore, starting from FIG. 4, the layer sequence is shown rotated in the subsequent figures, so that top and bottom are interchanged in FIG. 4 compared with FIG. 3.

An explanation is given below, with reference to FIG. 5 of substeps of the method for fabricating a planar double-gate transistor which principally serve for forming a second gate region of the planar double-gate transistor.

The first silicon layer 201 (carrier layer) of the SOI wafer is removed from the layer sequence from FIG. 4. This is preferably carried out by means of grinding or by means of so-called smart cut. Afterward, in an eighth etching step, possible residues of the first silicon layer 201 are etched back selectively by means of alkaline solutions. The etching back may be performed for example by means of ethylene diamine pyrocatechol (EDP), tetramethylammonium hydroxide (TMAH), potassium hydroxide (KOH) or choline (2-hydroxyethyl-trimethyl-ammonium hydroxide). The etching solutions enumerated have a high selectivity with respect to silicon-germanium if the proportion of germanium is higher than 20%. Furthermore, silicon-carbon is also well suited as an etch stop for most alkaline solutions. This high selectively greatly simplifies the eighth etching step by means of which possible residues of the first silicon layer 201 are removed. Silicon nitride and silicon oxide also act as an etch stop, particularly if etching is effected by means of alkaline solutions.

The first silicon oxide layer 202 is subsequently removed in a ninth etching step. An etchant that is selective with respect to silicon, silicon-germanium-carbon and silicon nitride is used for this purpose. This step defines the region in which the second gate region, the upper gate region, is formed. The ninth etching step ensures the self-alignment of the second gate region since only the first silicon oxide layer 202, which is arranged precisely above the lower gate region, is etched in this etching step. The following act as an etch stop: the second silicon layer 203 of the channel region, the silicon-germanium-carbon layer 310, which forms the source/drain regions, and the first silicon nitride layer 204, which is still situated above the lower gate region 206 and which cannot be discerned in FIG. 5 since, in the viewing direction of FIG. 5, it lies behind the sectional line along which the section of the layer sequence is taken. In this case, as already described, the first silicon nitride layer 204 has the same thickness as the second silicon layer 203. This was ensured by the first planarization step. In this case, the silicon-germanium-carbon layer 310 forms the lateral boundary of the region which is etched, and supports the self-alignment of the fabrication method by this delimitation.

A fourth layer made of silicon nitride 514 is subsequently formed in the region that has been etched back by the ninth etching step. Spacers serving for encapsulating the second gate region, that is to say the upper gate region, are formed from said fourth silicon nitride layer 514 by means of a subsequent anisotropic etching in a tenth etching step. A silicon oxide layer is preferably formed prior to the formation of the fourth layer 514 made of silicon nitride in the same region.

An oxidation step is subsequently carried out. The oxidation step serves for forming a sixth silicon oxide layer 515, which serves as a gate insulating layer, by partial oxidation from the second silicon layer 203 forming the channel region of the double-gate transistor. Furthermore, in this case, partial oxidation of the silicon-germanium-carbon layer 310 forms a thin seventh silicon oxide layer 516, which can prevent a diffusion during a doping step and which has a thickness of a few nm.

Afterward, a second polysilicon layer 517 is formed, which is subsequently planarized, preferably by means of chemical mechanical polishing. The thin seventh silicon oxide layer 516 may serve as a stop during the planarization step. The second polysilicon layer 517 forms the second gate region, that is to say the upper gate region, of the double-gate transistor. The second polysilicon layer 517, that is to say the upper gate region, is preferably subsequently etched back slightly, which makes it possible to prevent a short circuit from being able to occur between the upper gate region 517 and the silicon-germanium-carbon layer 310 forming the source/drain regions.

The formation of the second, and that is to say upper, gate region is concluded by means of the substeps described with reference to FIG. 5.

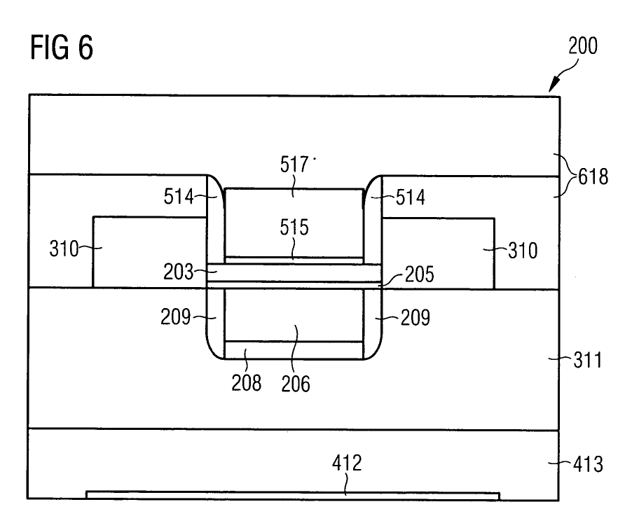

An explanation is given below, with reference to FIG. 6, of substeps of the method for fabricating a planar double-gate transistor which principally serve for forming an insulation of the double-gate transistor.

The source/drain regions formed by the silicon-germanium-carbon layer 310 and the upper gate region formed by the second polysilicon layer 517 are subsequently doped. In this case, the source/drain regions are doped at sufficient energy through the thin seventh silicon oxide layer 516, the seventh silicon oxide layer 516 being used as a so-called screen oxide layer which makes it possible to achieve a more homogeneous distribution of the doping atoms in the source/drain regions. The thin seventh silicon oxide layer 516 is subsequently removed by means of an eleventh selective etching step.

A slight selective etching back of the silicon-germanium-carbon layer 310 is subsequently carried out in a twelfth etching step. The twelfth etching step prevents a short circuit from being able to occur between the upper gate region 517 and the silicon-germanium-carbon layer 310 forming the source/drain regions.

A third photolithographic step is subsequently carried out, by means of which the active region is redefined and a second insulation is carried out, which enables a complete insulation of the entire double-gate transistor. For the third photolithographic step, a photoresist is applied using a third mask corresponding to the line 117 in FIG. 1. After application and development of the photoresist, parts of the silicon-germanium-carbon layer 310 are etched in a thirteenth etching step. The fifth silicon oxide layer 413 serves as an etch stop. Afterward, the residues of the photoresist are removed and a thick eighth layer made of silicon oxide 618 is deposited on the layer sequence. The eighth silicon oxide layer 618 is the layer which ensures the insulation of the entire double-gate transistor toward the outside.

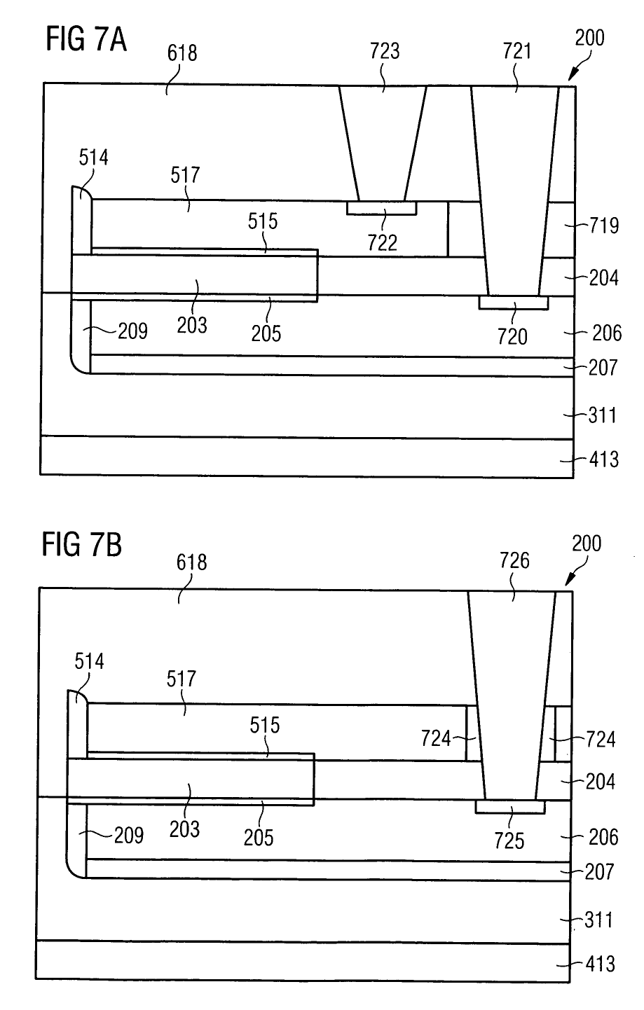

An explanation is given below, with reference to FIGS. 7A and 7B, of two alternatives in respect of how the two gate regions of the planar double-gate transistor can be contact-connected. The cross sections of FIGS. 7A and 7B are taken along the line G-G in FIG. 1 in this case.

With reference to FIG. 7A, an explanation is given of an exemplary embodiment in which a first contact-connection is formed for the upper gate region 517 and in which a second contact-connection is formed for the lower gate region 206. Consequently, different voltages can be applied to the upper gate region 517 and to the lower gate region 206. This is advantageous for example if the planar double-gate transistor is intended to be used as a memory cell which can store two bits independently of one another.

Proceeding from the layer sequence as illustrated in FIG. 6, a fourth photolithographic step is carried out, for which a photoresist is applied using a fourth mask corresponding to the line 118 in FIG. 1. An anisotropic fourteenth etching step is subsequently carried out, which removes a partial region, in which the formation of the contact-connection for the lower gate region 206 is subsequently carried out, of the eighth silicon oxide layer 618, the second polysilicon layer 517 of the upper gate region serving as an etch stop layer. The second polysilicon layer 517 is subsequently removed in the uncovered region of the upper gate region 517 in an anisotropic fifteenth etching step, the first silicon nitride layer 204 being used as an etch stop layer.

The photoresist residues still present are subsequently removed. Afterward, a controlled thermal oxidation of the second polysilicon layer 517 is carried out, which oxidation oxidizes regions of the second polysilicon layer 517 that were uncovered by means of the fifteenth etching step to form a ninth silicon oxide layer 719. The ninth silicon oxide layer 719 serves as insulation of the contact-connection for the first gate region 206 from the second gate region, so that no short circuit is caused between the two gate regions and so that a different voltage can be applied to the two gate regions.

Afterward, that region of the first silicon nitride layer 204 which was uncovered in the fifteenth etching step is removed in an anisotropic sixteenth etching step, as a result of which the lower gate region 206, that is to say parts of the first polysilicon layer 206, are uncovered. The first polysilicon layer 206 of the lower gate region is used as an etch stop for this sixteenth etching step. Afterward, a thin metal layer is formed on that region of the lower gate region 206 which was uncovered by the sixteenth etching step, and the first polysilicon layer 206 of the lower gate region 206 is silicided, thereby forming a first silicide layer 720, which reduces the contact resistance of the contact-connection of the lower gate region 206. A first metal layer 721 is subsequently formed on the first silicide layer 720, said first metal layer representing the contact to the lower gate region 206.

The contact-connection of the lower gate region 206 is concluded by means of the substeps described.

A contact-connection of the second polysilicon layer 517, that is to say of the upper gate 517, is subsequently formed in a corresponding manner, a second silicide layer 722 and a second metal layer 723 being formed.

In order to form the contact-connection of the upper gate region 517, a fifth photolithographic step is carried out. For this purpose, a photoresist is applied using a fifth mask essentially corresponding to the contour line of the second contact region 105 in FIG. 1. An anisotropic seventeenth etching step is subsequently carried out, which removes a partial region, in which the formation of the contact-connection for the upper gate region 517 is subsequently carried out, of the fifth silicon oxide layer 513, the second polysilicon layer 517 of the upper gate region serving as an etch stop layer.

A thin metal layer is subsequently formed on that region of the upper gate region 517 which was uncovered by the seventeenth etching step, and the second polysilicon layer 517 of the upper gate region is silicided, thereby forming a second silicide layer 722, which reduces the contact resistance of the contact-connection of the upper gate region 517. A second metal layer 723 is subsequently formed on the second silicide layer 722, said second metal layer representing the contact to the upper gate region 517.

The planar double-gate transistor is formed by means of the substeps of the method for fabricating a planar double-gate transistor as described with reference to FIG. 7A.

With reference to FIG. 7B, an explanation is given of an exemplary embodiment in which a common contact-connection is formed for the upper gate region 517 and the lower gate region 206. Consequently, the same voltage can be applied to the upper gate region 517 and to the lower gate region 206 and it is possible to use the control effect of both gate regions for the channel region.

Proceeding from the layer sequence as illustrated in FIG. 6, a sixth photolithographic step is carried out, for which a photoresist is applied using a fourth mask corresponding to the line 118 in FIG. 1. An anisotropic eighteenth etching step is subsequently carried out, which removes a partial region, in which the formation of the contact-connection for the two gate regions is subsequently carried out, of the fifth silicon oxide layer 513, the second polysilicon layer 517 of the upper gate region serving as an etch stop layer. The second polysilicon layer 517 is subsequently removed in the uncovered region of the upper gate region in an anisotropic eighteenth etching step, the first silicon nitride layer 204 being used as an etch stop layer.

The photoresist residues still present are subsequently removed. Afterward, a thin third metal layer is applied to the uncovered regions of the second polysilicon layer 517 and the uncovered regions of the second polysilicon layer 517 are silicided, thereby forming a third silicide layer 724, which reduces the contact resistance of the contact-connection of the upper gate region 517.

That region of the first silicon nitride layer 204 which was uncovered in the eighteenth etching step is subsequently removed in an anisotropic nineteenth etching step, as a result of which the lower gate, that is to say parts of the first polysilicon layer 206, are uncovered. The first polysilicon layer 206 of the lower gate region is used as an etch stop for this nineteenth etching step. Afterward, a thin metal layer is formed on that region of the lower gate region which was uncovered by the nineteenth etching step, and the first polysilicon layer 206 of the lower gate region is silicided, thereby forming a fourth silicide layer 725, which reduces the contact resistance of the contact-connection of the lower gate region 206. A third metal layer 726 is subsequently formed on the fourth silicide layer 725, said third metal layer representing the contact to the lower gate region 206. As an alternative to two separate siliciding steps by means of which the third silicide layer 724 and the fourth silicide layer 725 are formed, the third silicide layer 724 and the fourth silicide layer 725 may also be formed by means of a single process step, that is to say by means of a single siliciding step, that is to say that no siliciding for forming the third silicide layer 724 is carried out before the anisotropic nineteenth etching step.

By means of the substeps described, the contact-connection of the two gate regions is concluded and the planar double-gate transistor is formed.

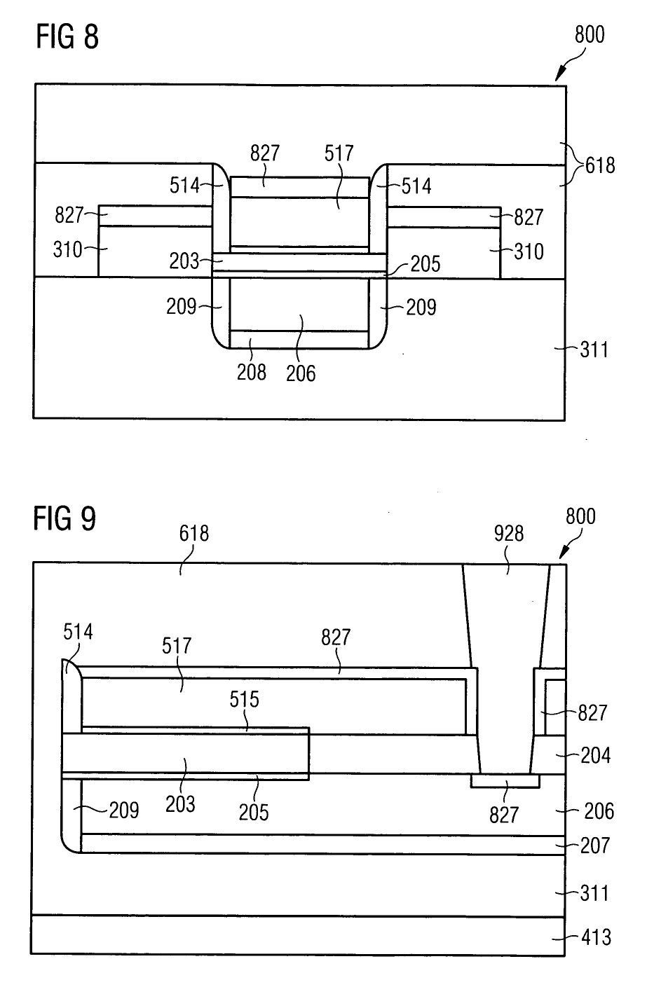

An alternative method is described with reference to FIG. 8 and FIG. 9.

The method steps of the alternative described here are identical to the method steps described with reference to FIG. 2 to FIG. 5. Changes arise with respect to the method described with reference to FIG. 6 and FIG. 7B. The alternative method described here essentially differs by the fact that a joint siliciding of the layer made of germanium-silicon-carbon 310, of the lower gate region 206 and of the upper gate region 517 is carried out within one siliciding step. For this purpose, prior to the formation of the eighth silicon oxide layer 618, an etching step is carried out by means of which a contact-connection of the first polysilicon layer 206, that is to say of the lower gate region 206, is performed by uncovering partial regions of the first polysilicon layer 206.

Afterward, in a joint siliciding step, a siliciding layer 827 is formed on the uncovered partial region of the first polysilicon layer 206, the silicon-germanium-carbon layer 310 and the second polysilicon layer 517. The eighth silicon oxide layer 618 is subsequently formed, as a result of which the layer sequence 800 illustrated in FIG. 8 is formed.

The further steps of the alternative method described here are carried out in accordance with the methods described above with reference to FIG. 7B. A double-gate field effect transistor in accordance with FIG. 9 results therefrom in the cross-sectional view G-G in accordance with FIG. 1.

To summarize, the invention relates to a method for fabricating a planar self-aligned double-gate transistor which has recourse to known, simple and cost-effective substeps of semiconductor technology. As a result of the invention's combination of the individual substeps, a planar double-gate transistor is fabricated in which short-channel effects are drastically reduced by the control effect of two gate regions. Furthermore, the fabrication process is simplified by the use of a layer made of silicon-germanium-carbon as source/drain region, this use having been unknown hitherto in the fabrication of double-gate transistors. The use of silicon-germanium and in particular the use of silicon-germanium-carbon has advantages over the conventional materials.

One advantage is that silicon-germanium-carbon is a suitable material for preventing or at least drastically reducing diffusion of dopants, e.g. the diffusion of dopants into the channel region, thereby enabling a better and more reliable control of the channel region. A second advantage is that additional possibilities are provided in the fabrication process because it is possible to use etchants which act selectively with respect to silicon-germanium-carbon. The utilization of the selectivity of the etchants with respect to silicon-germanium-carbon opens up new degrees of freedom in the fabrication process.

An additional advantage of the method according to the invention is that the source/drain regions are formed on a thick silicon layer of a silicon-on-insulator layer substrate wafer, that is to say the layer situated beneath the insulator layer (carrier layer), while in the known methods the source/drain regions are formed on a thin silicon layer of the silicon-on-insulator substrate, that is to say the silicon layer situated above the insulator layer. This simplifies the formation of the layer from which the source/drain regions are produced since, by way of example, mechanical stress is reduced during the formation.

1-18. (canceled)

19. A method for fabricating a planar double-gate transistor, comprising the steps of:
defining an active area on a silicon-on-insulator substrate of a first wafer;
forming a first gate region on the silicon-on-insulator substrate of the first wafer;
forming source/drain regions from a layer made of silicon-germanium in the active area, wherein a silicon layer that remains between the source and drain regions is provided as a channel region;
forming a layer having a planar surface above the silicon-on-insulator substrate, the source/drain regions, and the first gate region;
bonding a second wafer to the planar surface of the first wafer; and
forming a second gate region opposite the first gate region.

20. The method as claimed in claim 19, wherein the layer made of silicon-germanium further comprises carbon.

21. The method as claimed in claim 19, wherein the insulator of the silicon-on-insulator substrate is fabricated from silicon oxide.

22. The method as claimed in claim 19, wherein the active area of the silicon layer of the silicon-on-insulator substrate of the first wafer has a tablelike MESA structure.

23. The method as claimed in claim 22, further comprising the step of forming a first insulator layer on the silicon-on-insulator substrate of the first wafer in regions not covered by the MESA structure, wherein the first insulator layer has the same thickness as the silicon layer of the MESA structure.

24. The method as claimed in claim 23, wherein the step of forming the source/drain regions comprises the steps of:
patterning the uncovered silicon layer of the silicon-on-insulator substrate of the first wafer, wherein an encapsulation of the first gate region is used as a mask;
patterning the first insulator layer;
patterning the insulator layer of the silicon-on-insulator substrate of the first wafer; and
forming the silicon-germanium-carbon layer of the source/drain regions.

25. The method as claimed in claim 24, wherein the step of forming the silicon-germanium-carbon layer is carried out by means of selective epitaxy.

26. The method as claimed in claim 19, wherein the step of forming the first gate region on the silicon-on-insulator substrate comprises the steps of:
forming a first gate insulating layer on the silicon-on-insulator substrate;
forming and patterning a first layer made of an electrically conductive material on the first gate insulating layer; and
partially encapsulating the first gate region with an electrically nonconductive material.

27. The method as claimed in claim 26, wherein the first gate insulating layer is formed from silicon oxide produced by oxidation of the silicon layer of the silicon-on-insulator substrate of the first wafer.

28. The method as claimed in claim 19, wherein the silicon-germanium layer is formed by means of selective epitaxy.

29. The method as claimed in claim 19, wherein the step of forming the layer having a planar surface comprises the step of forming a planar first layer made of electrically nonconductive material on the silicon-germanium-carbon layer of the source/drain regions and the first gate region.

30. The method as claimed in claim 20, wherein the step of forming the second gate region comprises the steps of:
patterning the insulator layer of the silicon-on-insulator substrate and uncovering the silicon layer of the silicon-on-insulator substrate;
forming a gate insulating layer from a first thin nonconductive layer on the silicon layer of the silicon-on-insulator substrate and forming a second thin nonconductive layer on the layer made of SiGe:C of the source/drain regions; and
forming sidewall layers made of a nonconductive material.

31. The method as claimed in claim 30, wherein the thin nonconductive layer is produced by means of oxidation of the silicon layer of the silicon-on-insulator substrate and the layer made of SiGe:C of the source/drain regions.

32. The method as claimed in claim 30, wherein the step of forming the second gate region further comprises the steps of:
forming a second layer made of an electrically conductive material on the gate insulating layer;
etching back the silicon-germanium-carbon layer of the source/drain regions; and
forming a passivation layer on the entire wafer of the silicon-on-insulator substrate.

33. The method as claimed in claim 32, further comprising the steps of:
contact-connecting the first gate region; and
contact-connecting the second gate region.

34. The method as claimed in claim 33, wherein the step of contact-connecting the first gate region comprises the steps of:
uncovering a partial region of the second gate region by removing a part of the passivation layer;
uncovering a partial region of the first insulator layer by removing the second gate region in the partial region that has been uncovered;
uncovering a partial region of the first gate region by removing the first insulator layer in the partial region that has been uncovered; and
forming the contact-connection of the first gate region.

35. The method as claimed in claim 34, wherein, prior to the removal of the first insulator layer, a nonconductive layer is formed by oxidizing the uncovered regions of a conductive layer which forms the second gate region.

36. The method as claimed in claim 32, further comprising the step of common contact-connecting the first gate region and the second gate region.

37. A planar double-gate transistor, comprising:
a source region and a drain region;
a channel region arranged between the source region and the drain region; and
precisely two gates arranged on mutually opposite sides of the channel region,
wherein the source region and the drain region have silicon-germanium-carbon as material, and the germanium proportion is between 20% and 40%.
